(19) United States
(12) Patent Application Publication
(10) Pub. No.: US 2025/0357116 A1
(43) Pub. Date: Nov. 20, 2025

(54) SEMICONDUCTOR DEVICE

(71) Applicant: SAMSUNG ELECTRONICS CO., LTD., Suwon-si (KR)

(72) Inventors: Suk Yang, Suwon-si (KR); Jinbum Kim, Suwon-si (KR); Sung-Hwan Jang, Suwon-si (KR); Inhae Zoh, Suwon-si (KR); Bong Jin Kuh, Suwon-si (KR)

(21) Appl. No.: 18/958,617

(22) Filed: Nov. 25, 2024

(30) Foreign Application Priority Data
May 20, 2024 (KR) 10-2024-0065213

(51) Int. Cl. H01L 21/02; H01L 21/8256; H01L 27/092; H01L 29/24; H01L 29/66; H01L 29/76; H01L 29/786

(52) U.S. Cl. CPC H01L 21/02488; H01L 21/0243; H01L 21/02568; H10D 30/6757; H10D 48/362; H10D 62/80; H10D 84/02; H10D 84/85; H10D 99/00

(57) ABSTRACT

A semiconductor device includes a semiconductor pattern protruding in a direction perpendicular to a top surface of a substrate and having an inner surface and an outer surface that stand opposite to each other in a first direction parallel to the top surface of the substrate, a gate dielectric layer covering the inner surface and the outer surface of the semiconductor pattern and extending onto a top surface of the semiconductor pattern, a gate electrode on the gate dielectric layer and covering the outer surface, the top surface, and the inner surface of the semiconductor pattern, and an auxiliary pattern between the gate dielectric layer and the inner surface of the semiconductor pattern. The outer surface of the semiconductor pattern is in contact with the gate dielectric layer. The inner surface of the semiconductor pattern is in contact with the auxiliary pattern.

### CROSS-REFERENCE TO RELATED APPLICATION

This application claims priority under 35 U.S.C § 119 to Korean Patent Application No. 10-2024-0065213, filed on May 20, 2024, in the Korean Intellectual Property Office, the entirety of which is hereby incorporated by reference.

### BACKGROUND

A semiconductor device includes an integrated circuit including metal oxide semiconductor field effect transistors (MOSFETs). As sizes and design rules of the semiconductor device are gradually decreased, sizes of the MOSFETs are also increasingly scaled down. The scale down of MOSFETs may deteriorate operating characteristics of the semiconductor device. Accordingly, various research has been conducted to develop methods of fabricating semiconductor devices having superior performance while overcoming issues associated with high integration of the semiconductor devices.

### SUMMARY

Some aspects of the present disclosure provide semiconductor devices including a field effect transistor with increased effective channel width, and methods of fabricating the same.

Some aspects of the present disclosure provide semiconductor devices including a field effect transistor with excellent channel characteristics, and methods of fabricating the same.

According to some implementations of the present disclosure, a semiconductor device may include: a semiconductor pattern on a substrate, the semiconductor pattern protruding in a direction perpendicular to a top surface of the substrate and having an inner surface and an outer surface that stand opposite to each other in a first direction parallel to the top surface of the substrate; a gate dielectric layer that covers the inner surface and the outer surface of the semiconductor pattern, the gate dielectric layer extending onto a top surface of the semiconductor pattern; a gate electrode on the gate dielectric layer, the gate electrode covering the outer surface, the top surface, and the inner surface of the semiconductor pattern; and an auxiliary pattern between the gate dielectric layer and the inner surface of the semiconductor pattern. The outer surface of the semiconductor pattern may be in contact with the gate dielectric layer. The inner surface of the semiconductor pattern may be in contact with the auxiliary pattern.

According to some implementations of the present disclosure, a semiconductor device may include: a pair of semiconductor patterns on a substrate, the pair of semiconductor patterns being spaced apart from each other in a first direction parallel to a top surface of the substrate and protruding in a direction perpendicular to the top surface of the substrate; a pair of auxiliary patterns between the pair of semiconductor patterns and correspondingly on inner surfaces of the pair of semiconductor patterns; a gate dielectric layer that covers the pair of semiconductor patterns and the pair of auxiliary patterns and extends onto the substrate between the pair of auxiliary patterns; and a gate electrode on the gate dielectric layer, the gate electrode covering the pair of semiconductor patterns and the pair of auxiliary patterns and extending on the substrate between the pair of auxiliary patterns.

According to some implementations of the present disclosure, a semiconductor device may include: a semiconductor pattern on a substrate and protruding in a direction perpendicular to a top surface of the substrate, wherein the semiconductor pattern has an inner surface and an outer surface that stand opposite to each other in a direction parallel to the top surface of the substrate and extends in a second direction that is parallel to the top surface of the substrate and is cross to the first direction; an auxiliary pattern on the inner surface of the semiconductor pattern, the auxiliary pattern extending in the second direction; a gate electrode that covers the semiconductor pattern and the auxiliary pattern and extends in the first direction to run across the semiconductor pattern and the auxiliary pattern; a gate dielectric layer between the semiconductor pattern and the gate electrode, the gate dielectric layer extending between the auxiliary pattern and the gate electrode; and a plurality of source/drain electrodes on opposite sides of the gate electrode. On one side of the gate electrode, each of the source/drain electrodes may cover the semiconductor pattern and the auxiliary pattern.

### BRIEF DESCRIPTION OF DRAWINGS

FIG. 1 is a plan view showing an example of a semiconductor device.

FIG. 2A is a cross-sectional view taken along line A-A′ of FIG. 1.

FIG. 2B is a cross-sectional view taken along line B-B′ of FIG. 1.

FIG. 2C is a cross-sectional view taken along lines C-C′ and D-D′ of FIG. 1.

FIG. 3 is a cross-sectional view taken along line A-A′ of FIG. 1, showing an example of a semiconductor device.

FIG. 4 a cross-sectional view taken along line B-B′ of FIG. 1, showing an example of a semiconductor device.

FIGS. 5, 7, 9, 11, 13, 15, and 17 are plan views showing an example of a method of fabricating a semiconductor device.

FIGS. 6, 8, 10, 12, 14, 16, and 18 are cross-sectional views taken along line A-A′ of FIGS. 5, 7, 9, 11, 13, 15, and 17, respectively.

### DETAILED DESCRIPTION

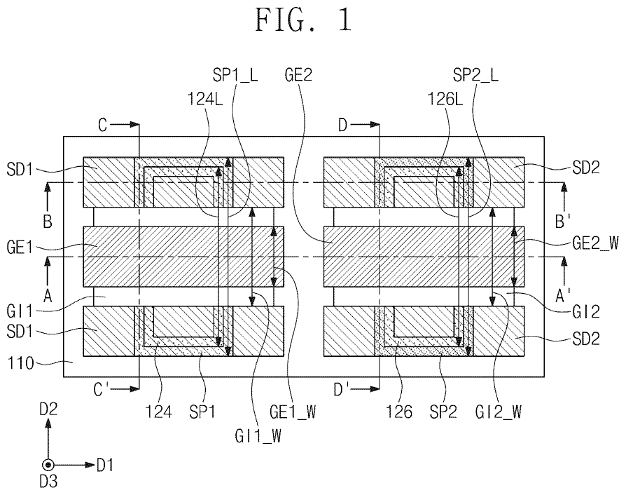

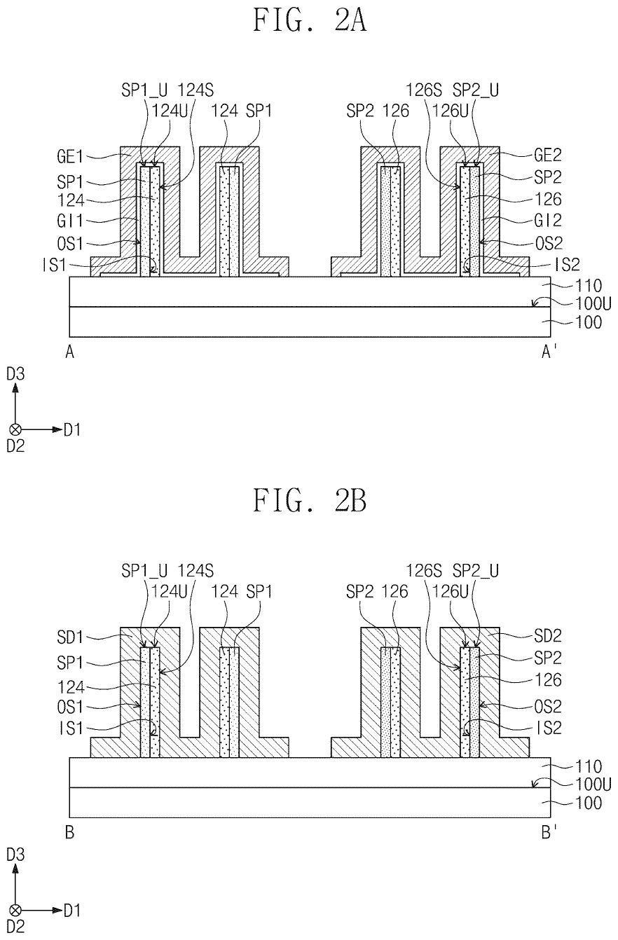

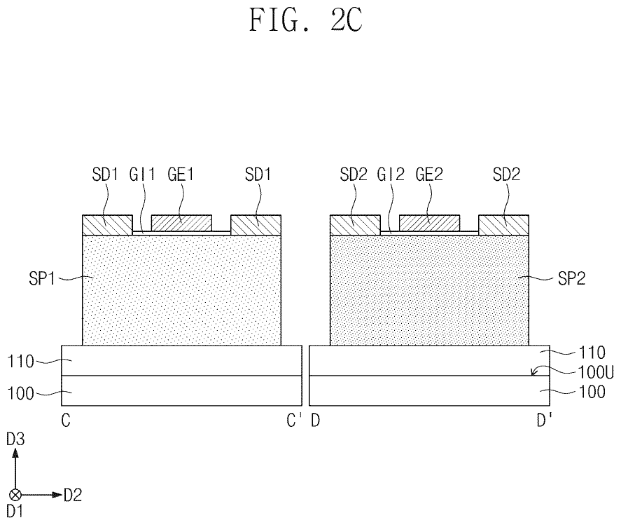

FIG. 1 is a plan view showing a semiconductor device according to some implementations of the present disclosure. For clarity of illustration, FIG. 1 illustrates some elements in a cut-away fashion, e.g., as opposed to only showing top-most layers. FIG. 2A illustrates a cross-sectional view taken along line A-A′ of FIG. 1. FIG. 2B illustrates a cross-sectional view taken along line B-B′ of FIG. 1. FIG. 2C illustrates a cross-sectional view taken along lines C-C′ and D-D′ of FIG. 1.

Referring to FIGS. 1 and 2A to 2C, a lower dielectric layer 110 may be disposed on a substrate 100. The substrate 100 may be a semiconductor substrate, for example, a silicon substrate, a germanium substrate, a silicon-germanium substrate, or a silicon-on-insulator (SOI) substrate. The lower dielectric layer 110 may include, for example, silicon oxide, silicon nitride, or silicon oxynitride.

A pair of first semiconductor patterns SP1 (e.g., the left half and right half of SP1, respectively, as illustrated in FIG. 1) may be disposed on the lower dielectric layer 110. The first semiconductor patterns SP1 may be at least partially spaced apart from each other in a first direction D1, and may extend in a second direction D2. The first direction D1 and the second direction D2 may be parallel to a top surface 100U of the substrate 100 and may be cross to each other. The first semiconductor patterns SP1 may protrude from the lower dielectric layer 110 along a third direction D3 perpendicular to the top surface 100U of the substrate 100. In some implementations, each of the first semiconductor patterns SP1 has end portions that are opposite to each other in the second direction D2, and the end portions of the first semiconductor patterns SP1 may extend in the first direction D1 to connect with each other. Therefore, the first semiconductor patterns SP1 may be connected to each other to constitute a ring shape or other closed shape in a plan view (e.g., rectangular shape) that extends in the second direction D2. For example, the first semiconductor patterns SP1 need not form separate portions of material but, rather, in some implementations form a single continuous portion of material, e.g., having a closed shape in a plan view. Each of the first semiconductor patterns SP1 may have a first inner surface IS1 and a first outer surface OS1 that stand opposite to each other in the first direction D1. The first inner surfaces IS1 of the first semiconductor patterns SP1 may face each other.

A pair of first auxiliary patterns 124 (e.g., the left half and right half of 124, respectively, as illustrated in FIG. 1) may be disposed between the first semiconductor patterns SP1, and may be correspondingly arranged on the first inner surfaces IS1 of the first semiconductor patterns SP1. The first auxiliary patterns 124 may be at least partially spaced apart from each other in the first direction D1, and may extend in the second direction D2. The first auxiliary patterns 124 may protrude along the third direction D3 from the lower dielectric layer 110. The first auxiliary patterns 124 may be correspondingly in contact with the first inner surfaces IS1 of the first semiconductor patterns SP1. According to some implementations, each of the first auxiliary patterns 124 has end portions that are arranged opposite to each other in the second direction D2, and the end portions of the first auxiliary patterns 124 may extend in the first direction D1 to connect with each other. Thus, the first auxiliary patterns 124 may be connected to each other to constitute a ring shape or other closed shape that extends in the second direction D2. For example, the first auxiliary patterns 124 need not form separate portions of material but, rather, in some implementations form a single continuous portion of material, e.g., having a closed shape in a plan view. The ring-shaped (or other closed-shape) first auxiliary patterns 124 may extend along and contact with the first inner surfaces IS1 of the ring-shaped (or other closed-shaped) first semiconductor patterns SP1.

A first gate dielectric layer GI1 may cover the first semiconductor patterns SP1 and the first auxiliary patterns 124, and may extend in the first direction D1 to extend across the first semiconductor patterns SP1 and the first auxiliary patterns 124. The first gate dielectric layer GI1 may cover the first outer surfaces OS1 and top surfaces SP1_U of the first semiconductor patterns SP1, and may extend onto/above the first inner surfaces IS1 of the first semiconductor patterns SP1 to cover the first auxiliary patterns 124. The first gate dielectric layer GI1 may extend onto the lower dielectric layer 110 between the first auxiliary patterns 124. The first gate dielectric layer GI1 may contact the first outer surfaces OS1 and the top surfaces SP1_U of the first semiconductor patterns SP1, and may extend onto top surface 124U and lateral surfaces 124S of the first auxiliary patterns 124. The first gate dielectric layer GI1 may be spaced apart from the first inner surfaces IS1 of the first semiconductor patterns SP1 across the first auxiliary patterns 124. Each of the first auxiliary patterns 124 may be interposed between the first gate dielectric layer GI1 and the first inner surface IS1 of each of the first semiconductor patterns SP1.

A first gate electrode GE1 may be disposed on the first gate dielectric layer GI1, and may extend in the first direction D1 to extend across the first semiconductor patterns SP1 and the first auxiliary patterns 124. The first gate electrode GE1 may cover the first outer surfaces OS1 and the top surface SP1_U of the first semiconductor patterns SP1, and may extend onto/above the first inner surfaces IS1 of the first semiconductor patterns SP1 to cover the first auxiliary patterns 124. The first gate electrode GE1 may extend onto the lower dielectric layer 110 between the first auxiliary patterns 124. According to some implementations, the first gate electrode GE1 partially fills a space between the first auxiliary patterns 124.

The first gate dielectric layer GI1 may be interposed between the first gate electrode GE1 and each of the first semiconductor patterns SP1, and may extend between the first gate electrode GE1 and each of the first auxiliary patterns 124 and between the lower dielectric layer 110 and the first gate electrode GE1.

A length SP1_L in the second direction D2 of each of the first semiconductor patterns SP1 may be greater than a width GI1_W in the second direction D2 of the first gate dielectric layer GI1. A length 124L in the second direction D2 of each of the first auxiliary patterns 124 may be greater than the width GI1_W in the second direction D2 of the first gate dielectric layer GI1. The width GI1_W in the second direction D2 of the first gate dielectric layer GI1 may be greater than a width GE1_W in the second direction D2 of the first gate electrode GE1.

First source/drain electrodes SD1 may be disposed on opposite sides of the first gate electrode GE1. The first source/drain electrodes SD1 may be spaced apart from each other in the second direction D2 across the first gate electrode GE1 and the first gate dielectric layer GI1. On either side of the first gate electrode GE1, the first source/drain electrodes SD1 may cover the first semiconductor patterns SP1 and the first auxiliary patterns 124. Each of the first source/drain electrodes SD1 may cover the first outer surfaces OS1 and the top surfaces SP1_U of the first semiconductor patterns SP1, and extend onto/above the first inner surfaces IS1 of the first semiconductor patterns SP1 to cover the first auxiliary patterns 124. Each of the first source/drain electrodes SD1 may extend onto the top surfaces 124U and the lateral surfaces 124S of the first auxiliary patterns 124. Each of the first source/drain electrodes SD1 may extend onto the lower dielectric layer 110 between the first auxiliary patterns 124. According to some implementations, each of the first source/drain electrodes SD1 partially fills a space between the first auxiliary patterns 124.

Each of the first source/drain electrodes SD1 may be spaced apart from the first inner surfaces IS1 of the first semiconductor patterns SP1 across the first auxiliary patterns 124. Each of the first auxiliary patterns 124 may be interposed between each of the first source/drain electrodes SD1 and the first inner surface IS1 of each of the first semiconductor patterns SP1.

A first fin field effect transistor may be constituted by the first semiconductor patterns SP1, the first auxiliary patterns 124, the first gate dielectric layer GI1, the first gate electrode GE1, and the first source/drain electrodes SD1. The first semiconductor patterns SP1 may be used as a channel of the first fin field effect transistor, and the first auxiliary patterns 124 may be used as a portion of a gate dielectric layer of the first fin field effect transistor. The first fin field effect transistor may be, for example, an n-type field effect transistor.

A pair of second semiconductor patterns SP2 (e.g., the left half and right half of SP2, respectively, as illustrated in FIG. 1) may be disposed on the lower dielectric layer 110. The second semiconductor patterns SP2 may be at least partially spaced apart from each other in the first direction D1, and may extend in the second direction D2. The second semiconductor patterns SP2 may protrude along the third direction D3 from the lower dielectric layer 110. The second semiconductor patterns SP2 may be spaced apart horizontally (e.g., in the first direction D1) apart from the first semiconductor patterns SP1. According to some implementations, each of the second semiconductor patterns SP2 has end portions that stand opposite to each other in the second direction D2, and the end portions of the second semiconductor patterns SP2 may extend in the first direction D1 to connect with each other. Therefore, the second semiconductor patterns SP2 may be connected to each other to constitute a ring shape or other closed shape in a plan view (e.g., rectangular shape) that extends in the second direction D2. For example, the second semiconductor patterns SP2 need not form separate portions of material but, rather, in some implementations form a single continuous portion of material, e.g., having a closed shape in a plan view. Each of the second semiconductor patterns SP2 may have a second inner surface IS2 and a second outer surface OS2 that stand opposite to each other in the first direction D1. The second inner surfaces IS2 of the second semiconductor patterns SP2 may face each other.

A pair of second auxiliary patterns 126 (e.g., the left half and right half of 126, respectively, as illustrated in FIG. 1) may be disposed between the second semiconductor patterns SP2, and may be correspondingly arranged on the second inner surfaces IS2 of the second semiconductor patterns SP2. The second auxiliary patterns 126 may be at least partially spaced apart from each other in the first direction D1, and may extend in the second direction D2. The second auxiliary patterns 126 may protrude along the third direction D3 from the lower dielectric layer 110. The second auxiliary patterns 126 may be correspondingly in contact with the second inner surfaces IS2 of the second semiconductor patterns SP2. According to some implementations, each of the second auxiliary patterns 126 has end portions that stand opposite to each other in the second direction D2, and the end portions of the second auxiliary patterns 126 may extend in the first direction D1 to connect with each other. Thus, the second auxiliary patterns 126 may be connected to each other to constitute a ring shape or other closed shape that extends in the second direction D2. For example, the second auxiliary patterns 126 need not form separate portions of material but, rather, in some implementations form a single continuous portion of material, e.g., having a closed shape in a plan view. The ring-shaped second auxiliary patterns 126 may extend along and contact with the second inner surfaces IS2 of the ring-shaped second semiconductor patterns SP2.

A second gate dielectric layer GI2 may cover the second semiconductor patterns SP2 and the second auxiliary patterns 126, and may extend in the first direction D1 to extend across the second semiconductor patterns SP2 and the second auxiliary patterns 126. The second gate dielectric layer GI2 may be spaced apart horizontally (e.g., in the first direction D1) from the first gate dielectric layer GI1. The second gate dielectric layer GI2 may cover the second outer surfaces OS2 and top surfaces SP2_U of the second semiconductor patterns SP2, and may extend onto/above the second inner surfaces IS2 of the second semiconductor patterns SP2 to cover the second auxiliary patterns 126. The second gate dielectric layer GI2 may extend onto the lower dielectric layer 110 between the second auxiliary patterns 126. The second gate dielectric layer GI2 may contact the second outer surfaces OS2 and the top surfaces SP2_U of the second semiconductor patterns SP2, and may extend onto top surface 126U and lateral surfaces 126S of the second auxiliary patterns 126. The second gate dielectric layer GI2 may be spaced apart from the second inner surfaces IS2 of the second semiconductor patterns SP2 across the second auxiliary patterns 126. Each of the second auxiliary patterns 126 may be interposed between the second gate dielectric layer GI2 and the second inner surface IS2 of each of the second semiconductor patterns SP2.

A second gate electrode GE2 may be disposed on the second gate dielectric layer GI2, and may extend in the first direction D1 to extend across the second semiconductor patterns SP2 and the second auxiliary patterns 126. The second gate electrode GE2 may be spaced apart horizontally (e.g., in the first direction D1) from the first gate electrode GE1. The second gate electrode GE2 may cover the second outer surfaces OS2 and the top surface SP2_U of the second semiconductor patterns SP2, and may extend onto/above the second inner surfaces IS2 of the second semiconductor patterns SP2 to cover the second auxiliary patterns 126. The second gate electrode GE2 may extend onto the lower dielectric layer 110 between the second auxiliary patterns 126. According to some implementations, the second gate electrode GE2 partially fills a space between the second auxiliary patterns 126.

The second gate dielectric layer GI2 may be interposed between the second gate electrode GE2 and each of the second semiconductor patterns SP2, and may extend between the second gate electrode GE2 and each of the second auxiliary patterns 126 and between the lower dielectric layer 110 and the second gate electrode GE2.

A length SP2_L in the second direction D2 of each of the second semiconductor patterns SP2 may be greater than a width GI2_W in the second direction D2 of the second gate dielectric layer GI2. A length 126L in the second direction D2 of each of the second auxiliary patterns 126 may be greater than the width GI2_W in the second direction D2 of the second gate dielectric layer GI2. The width GI2_W in the second direction D2 of the second gate dielectric layer GI2 may be greater than a width GE2_W in the second direction D2 of the second gate electrode GE2.

Second source/drain electrodes SD2 may be disposed on opposite sides of the second gate electrode GE2. The second source/drain electrodes SD2 may be spaced apart from each other in the second direction D2 across the second gate electrode GE2 and the second gate dielectric layer GI2. The second source/drain electrodes SD2 may be spaced apart horizontally (e.g., in the first direction D1) from the first source/drain electrodes SD1. On either side of the second gate electrode GE2, each of the second source/drain electrodes SD2 may cover the second semiconductor patterns SP2 and the second auxiliary patterns 126. Each of the second source/drain electrodes SD2 may cover the second outer surfaces OS2 and the top surfaces SP2_U of the second semiconductor patterns SP2, and may extend onto/above the second inner surfaces IS2 of the second semiconductor patterns SP2 to cover the second auxiliary patterns 126. Each of the second source/drain electrodes SD2 may extend onto the top surfaces 126U and the lateral surfaces 126S of the second auxiliary patterns 126. Each of the second source/drain electrodes SD2 may extend onto lower dielectric layer 110 between the second auxiliary patterns 126. According to some implementations, each of the second source/drain electrodes SD2 partially fills a space between the second auxiliary patterns 126.

Each of the second source/drain electrodes SD2 may be spaced apart from the second inner surfaces IS2 of the second semiconductor patterns SP2 across the second auxiliary patterns 126. Each of the second auxiliary patterns 126 may be interposed between each of the second source/drain electrodes SD2 and the second inner surface IS2 of each of the second semiconductor patterns SP2.

A second fin field effect transistor may be constituted by the second semiconductor patterns SP2, the second auxiliary patterns 126, the second gate dielectric layer GI2, the second gate electrode GE2, and the second source/drain electrodes SD2. The second semiconductor patterns SP2 may be used as a channel of the second fin field effect transistor, and the second auxiliary patterns 126 may be used as a portion of a gate dielectric layer of the second fin field effect transistor. The second fin field effect transistor may be, for example, a p-type field effect transistor.

The first semiconductor patterns SP1 and the second semiconductor patterns SP2 may include a two-dimensional semiconductor material, for example, a transition metal dichalcogenide. The transition metal dichalcogenide may be represented by the chemical formula MX₂, where M may be a transition metal from Groups 3 to 12, and X may be a chalcogen element (e.g., S, Se, or Te). The first semiconductor patterns SP1 and the second semiconductor patterns SP2 may include, for example, at least one selected from MoS₂, WS₂, MoSe₂, WSe₂, VSe₂, and TiS₂. The first semiconductor patterns SP₁ and the second semiconductor patterns SP2 may have a hexagonal closed-packed (HCP) crystalline structure.

According to some implementations, the first semiconductor patterns SP1 include a chalcogen element different from that of the second semiconductor patterns SP2. The first semiconductor patterns SP1 may include a transition metal disulfide, for example, at least one selected from MoS₂, WS₂, and TiS₂. The first semiconductor patterns SP1 may be used as a channel of an n-type field effect transistor. The second semiconductor patterns SP2 may include a transition metal diselenide, for example, at least one selected from MoSe₂, WSe₂, and VSe₂. The second semiconductor patterns SP2 may be used as a channel of a p-type field effect transistor.

The first auxiliary patterns 124 and the second auxiliary patterns 126 may include at least one selected from metal oxide and metalloid nitride. The first and second auxiliary patterns 124 and 126 may have an amorphous structure or a crystalline structure the same as or similar to that (e.g., an HCP or its similar crystalline structure) of the first and second semiconductor patterns SP1 and SP2. The first and second auxiliary patterns 124 and 126 may include, for example, at least one selected from crystalline aluminum oxide, amorphous aluminum oxide, amorphous hafnium oxide, and boron nitride (BN).

The first gate dielectric layer GI1 and the second gate dielectric layer GI2 may include at least one selected from a silicon oxide layer, a silicon nitride layer, a silicon oxynitride layer, and a high-k dielectric layer. The high-k dielectric layer may include a metal oxide layer, such as a hafnium oxide (HfO) layer, an aluminum oxide (AlO) layer, or a tantalum oxide (TaO) layer, whose dielectric constant is greater than that of a silicon oxide layer. The first gate electrode GE1 and the second gate electrode GE2 may include one or more of doped semiconductor, conductive metal nitride, and metal.

The first source/drain electrodes SD1 and the second source/drain electrodes SD2 may include metal, such as at least one selected from copper (Cu), gold (Au), silver (Ag), platinum (Pt), bismuth (Bi), antimony (Sb), and ruthenium (Ru). According to some implementations, the first source/drain electrodes SD1 includes metal different from that of the second source/drain electrodes SD2. The first source/drain electrodes SD1 may include, for example, at least one selected from bismuth (Bi) and antimony (Sb), and may be included in an n-type field effect transistor. The second source/drain electrodes SD2 may include, for example, ruthenium (Ru), and may be included in a p-type field effect transistor.

According to some implementations of the present disclosure, a fin field effect transistor includes a pair of semiconductor patterns SP1/SP2, auxiliary patterns 124/126 disposed between the semiconductor patterns SP1/SP2 and correspondingly on inner surfaces of the semiconductor patterns SP1/SP2, a gate electrode GE1/GE2 that runs across the semiconductor patterns SP1/SP2 and the auxiliary patterns 124/126, a gate dielectric layer GI1/GI2 interposed between the semiconductor patterns SP1/SP2 and the gate electrode GE1/GE2 and between the auxiliary patterns 124/126 and the gate electrode GE1/GE2, and source/drain electrodes SD1/SD2 disposed on opposite sides of the gate electrode GE1/GE2 and covering the semiconductor patterns SP1/SP2 and the auxiliary patterns 124/126. The semiconductor patterns SP1/SP2 may include a transition metal dichalcogenide, and thus the fin field effect transistor may be a field effect transistor having a transition metal dichalcogenide channel. As the fin field effect transistor includes the pair of semiconductor patterns SP1/SP2, the fin field effect transistor may have an increased effective channel width (W_{eff}).

Moreover, the auxiliary patterns 124/126 may assist a monocrystalline growth of the semiconductor patterns SP1/SP2 and support the semiconductor patterns SP1/SP2. Therefore, a crystalline growth of the semiconductor patterns SP1/SP2 may be easily and stably performed, and as a result, the fin field effect transistor may improve in channel characteristics.

Accordingly, according to some implementations of the present disclosure, fin field effect transistors may be provided with increased effective channel width and excellent channel characteristics.

FIG. 3 illustrates a cross-sectional view taken along line A-A′ of FIG. 1, showing an example of a semiconductor device. The semiconductor device discussed with respect to FIG. 3 is similar to that discussed with reference to FIGS. 1 and 2A to 2C, and thus the major differences between the semiconductor devices will be described below in the interest of brevity of description. Characteristics of the FIG. 3 device can be the same as those of the FIGS. 1 and 2A to 2C device, except where noted otherwise or suggested otherwise by context.

Referring to FIGS. 1 and 3, the first gate electrode GE1 may be disposed on the first gate dielectric layer GI1, and may extend in the first direction D1 to extend across the first semiconductor patterns SP1 and the first auxiliary patterns 124. According to some implementations, the first gate electrode GE1 completely fills a space between the first auxiliary patterns 124. The second gate electrode GE2 may be disposed on the second gate dielectric layer GI2, and may extend in the first direction D1 to extend across the second semiconductor patterns SP2 and the second auxiliary patterns 126. According to some implementations, the second gate electrode GE2 completely fills a space between the second auxiliary patterns 126. Except for these differences, the semiconductor device may be substantially the same as the semiconductor device discussed with reference to FIGS. 1 and 2A to 2C.

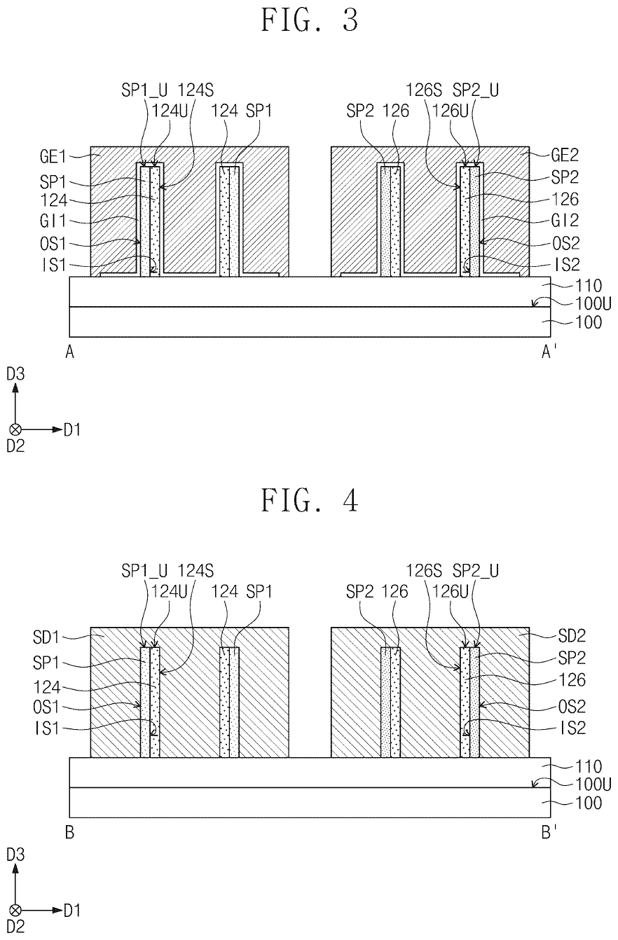

FIG. 4 illustrates a cross-sectional view taken along line B-B′ of FIG. 1, showing an example of a semiconductor device. The semiconductor device discussed with respect to FIG. 4 is similar to that discussed with reference to FIGS. 1 and 2A to 2C, and thus the major differences between the semiconductor devices will be described below in the interest of brevity of description. Characteristics of the FIG. 4 device can be the same as those of the FIGS. 1 and 2A to 2C device, except where noted otherwise or suggested otherwise by context.

Referring to FIG. 4, on one side of the first gate electrode GE1, each of the first source/drain electrodes SD1 may cover the first semiconductor patterns SP1 and the first auxiliary patterns 124. According to some implementations, each of the first source/drain electrodes SD1 completely fills a space between the first auxiliary patterns 124. On one side of the second gate electrode GE2, each of the second source/drain electrodes SD2 may cover the second semiconductor patterns SP2 and the second auxiliary patterns 126. According to some implementations, each of the second source/drain electrodes SD2 completely fills a space between the second auxiliary patterns 126. Except for these differences, the semiconductor device may be substantially the same as the semiconductor device discussed with reference to FIGS. 1 and 2A to 2C.

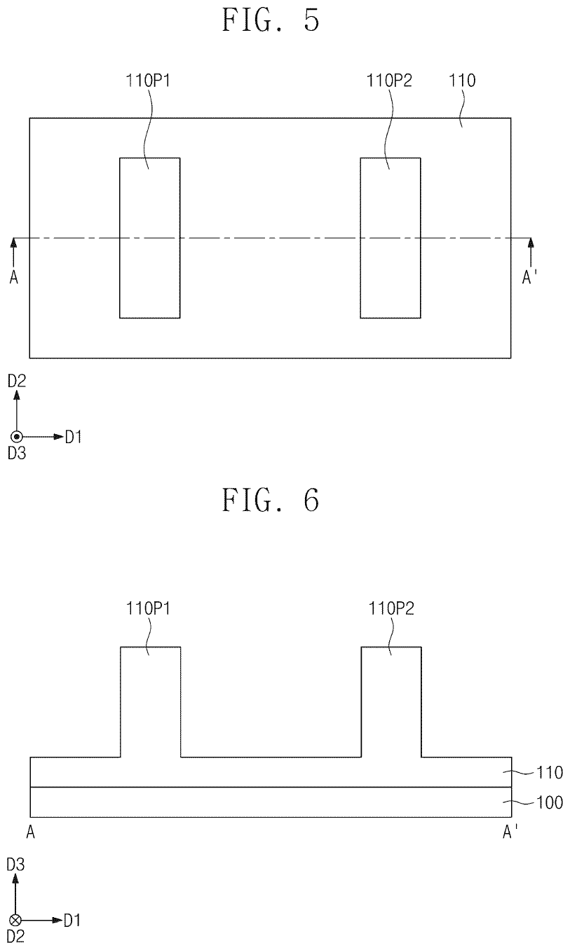

FIGS. 5, 7, 9, 11, 13, 15, and 17 illustrate plan views showing a method of fabricating a semiconductor device, e.g., the semiconductor device discussed with respect to FIGS. 1 and 2A to 2C. FIGS. 6, 8, 10, 12, 14, 16, and 18 illustrate cross-sectional views taken along line A-A′ of FIGS. 5, 7, 9, 11, 13, 15, and 17, respectively. For brevity of description, omission will be made to avoid repetitive explanation of the semiconductor device discussed with reference to FIGS. 1 and 2A to 2C.

Referring to FIGS. 5 and 6, a lower dielectric layer 110 may be formed on a substrate 100. A first mold pattern 110P1 and a second mold pattern 110P2 may be formed on the lower dielectric layer 110. The first mold pattern 110P1 and the second mold pattern 110P2 may be spaced apart from each other in the first direction D1, and may extend in the second direction D2. The first and second mold patterns 110P1 and 110P2 may protrude along the third direction D3 from the lower dielectric layer 110. The first and second mold patterns 110P1 and 110P2 may include, for example, silicon oxide, silicon nitride, or silicon oxynitride. The first and second mold patterns 110P1 and 110P2 may be, for example, portions of the lower dielectric layer 110 that are formed by patterning an upper portion of the lower dielectric layer 110.

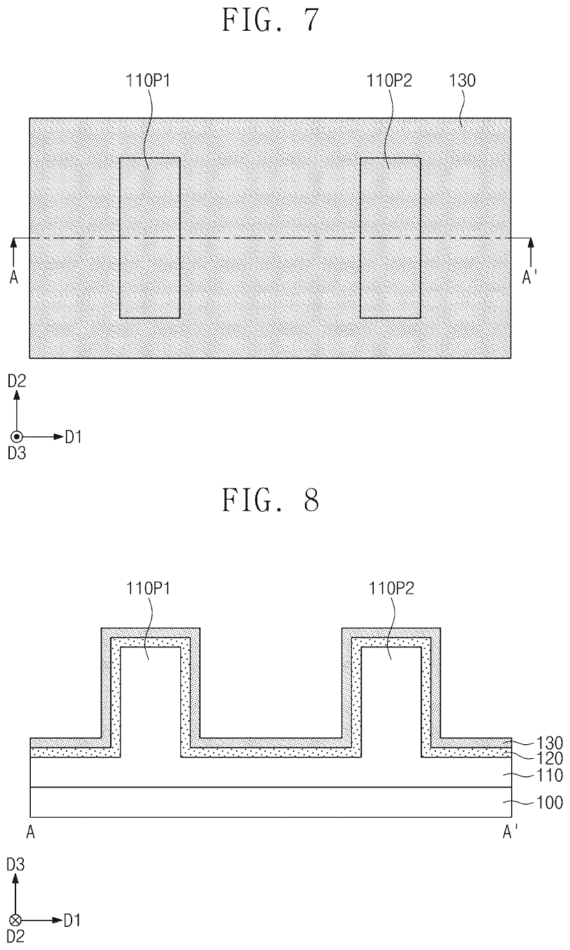

Referring to FIGS. 7 and 8, an auxiliary layer 120 and a seed layer 130 may be sequentially stacked on the lower dielectric layer 110. The auxiliary layer 120 may conformally cover top surfaces and lateral surfaces of the first and second mold patterns 110P1 and 110P2, and may extend onto a top surface of the lower dielectric layer 110. The auxiliary layer 120 may include at least one selected from metal oxide and metalloid nitride. The seed layer 130 may be formed on the auxiliary layer 120. The seed layer 130 may conformally cover the top surfaces and lateral surfaces of the first and second mold patterns 110P1 and 110P2, and may extend onto the top surface of the lower dielectric layer 110. The seed layer 130 may include transition metal, for example, at least one selected from W, Mo, V, and Ti. The auxiliary layer 120 and the seed layer 130 may be formed by, for example, chemical vapor deposition or physical vapor deposition.

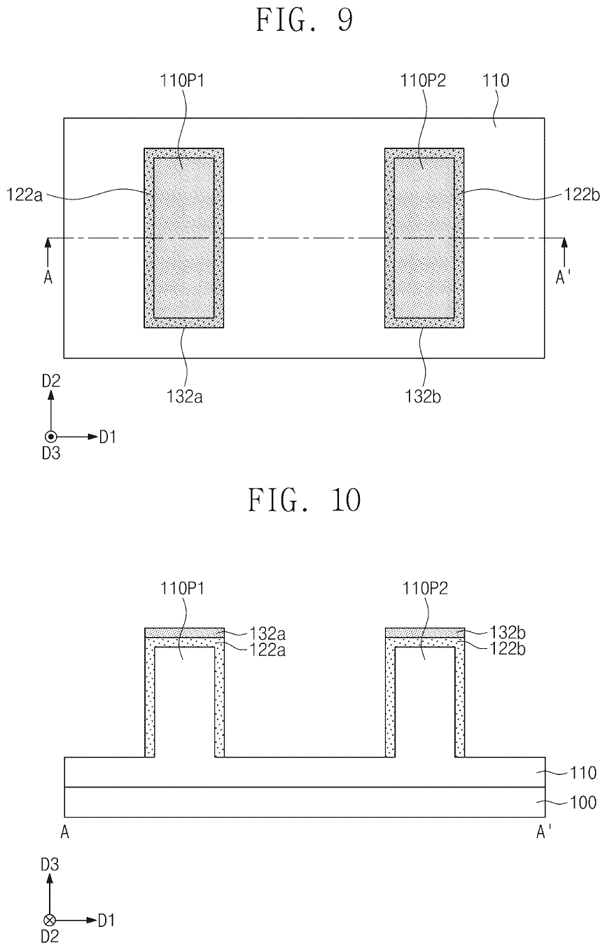

Referring to FIGS. 9 and 10, a first seed pattern 132a and a second seed pattern 132b may be respectively formed on the top surface of the first mold pattern 110P1 and the top surface of the second mold pattern 110P2. The formation of the first and second seed patterns 132a and 132b may include, for example, removing a portion of the seed layer 130 on the lateral surfaces of the first and second mold patterns 110P1 and 110P2 and on the top surface of the lower dielectric layer 110. The partial removal of the seed layer 130 may be performed by using, for example, a dry etching process or a wet etching process.

After the formation of the first and second seed patterns 132a and 132b, a first preliminary auxiliary pattern 122a and a second preliminary auxiliary pattern 122b may be respectively formed on the first mold pattern 110P1 and the second mold pattern 110P2. The first preliminary auxiliary pattern 122a may be interposed between the first seed pattern 132a and the top surface of the first mold pattern 110P1, and may extend onto the lateral surfaces of the first mold pattern 110P1. The second preliminary auxiliary pattern 122b may be interposed between the second seed pattern 132b and the top surface of the second mold pattern 110P2, and may extend onto the lateral surfaces of the second mold pattern 110P2. The formation of the first and second preliminary auxiliary patterns 122a and 122b may include removing a portion of the auxiliary layer 120 on the top surface of the lower dielectric layer 110. The partial removal of the auxiliary layer 120 may be performed by using, for example, a dry etching process or a wet etching process, and this removal process may be carried out until the top surface of the lower dielectric layer 110 is exposed.

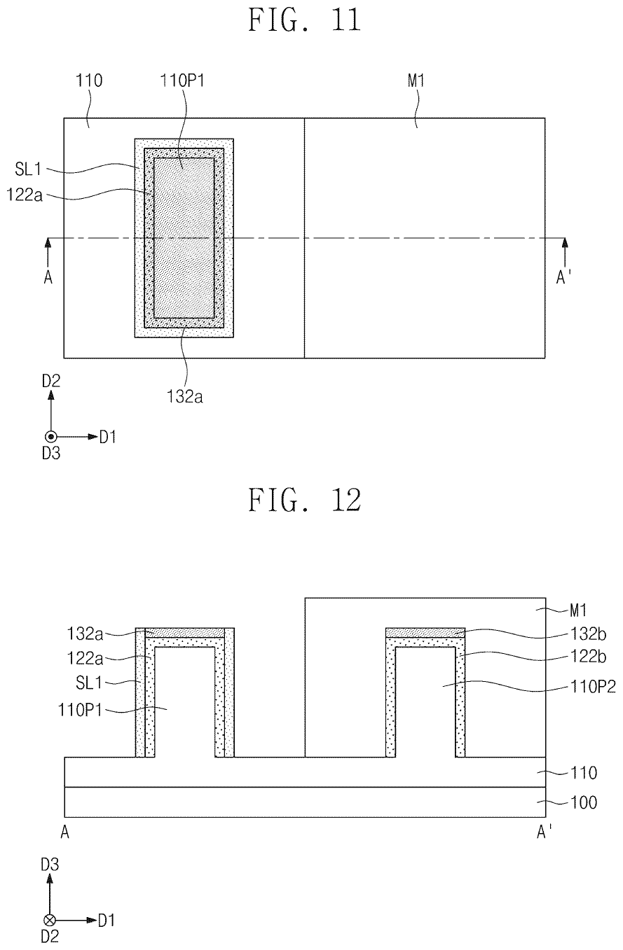

Referring to FIGS. 11 and 12, a first mask pattern M1 may be formed on the lower dielectric layer 110 to cover the second mold pattern 110P2, the second seed pattern 132b, and the second preliminary auxiliary pattern 122b. The first mask pattern M1 may be, for example, a photoresist pattern or a hardmask pattern. The first mask pattern M1 may expose the first mold pattern 110P1, the first seed pattern 132a, and the first preliminary auxiliary pattern 122a.

A first semiconductor layer SL1 may be formed on the lateral surfaces of the first mold pattern 110P1 and on the first preliminary auxiliary pattern 122a. The first semiconductor layer SL1 may be formed by a first selective growth process in which the first seed pattern 132a is used as a seed. The first selective growth process may be executed using a first precursor including transition metal and a second precursor including a chalcogen element. The first semiconductor layer SL1 may include a transition metal dichalcogenide. The first seed pattern 132a and the first semiconductor layer SL1 may include the same transition metal element. According to some implementations, the second precursor may include sulfur(S), and the first semiconductor layer SL1 includes a transition metal disulfide.

The first preliminary auxiliary pattern 122a may include a material (e.g., crystalline aluminum oxide, amorphous aluminum oxide, or amorphous hafnium oxide) having a high bonding energy with the first and second precursors of the first selective growth process, or a material (e.g., crystalline aluminum oxide or boron nitride (BN)) having an identical or similar crystalline structure (e.g., an HCP or its similar crystalline structure) to that of the first semiconductor layer SL1. Therefore, during the first selective growth process, the first preliminary auxiliary pattern 122a may assist a monocrystalline growth of the first semiconductor layer SL1.

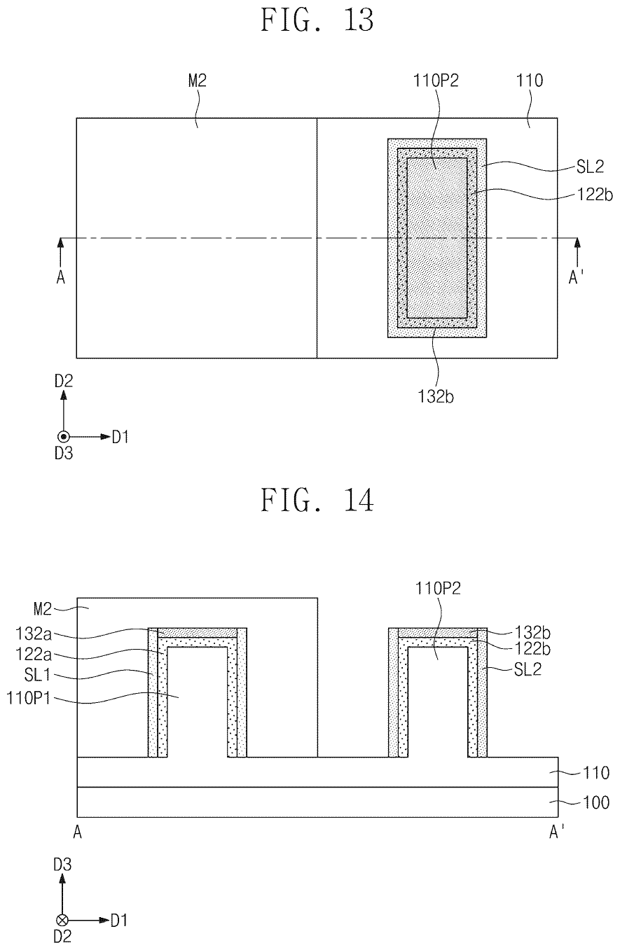

Referring to FIGS. 13 and 14, after the formation of the first semiconductor layer SL1, the first mask pattern M1 may be removed. The first mask pattern M1 may be removed by, for example, an ashing process and/or a strip process.

A second mask pattern M2 may be formed on the lower dielectric layer 110 to cover the first mold pattern 110P1, the first seed pattern 132a, the first preliminary auxiliary pattern 122a, and the first semiconductor layer SL1. The second mask pattern M2 may be, for example, a photoresist pattern or a hardmask pattern. The second mask pattern M2 may expose the second mold pattern 110P2, the second seed pattern 132b, and the second preliminary auxiliary pattern 122b.

A second semiconductor layer SL2 may be formed on the lateral surfaces of the second mold pattern 110P2 and on the second preliminary auxiliary pattern 122b. The second semiconductor layer SL2 may be formed by a second selective growth process in which the second seed pattern 132b is used as a seed. The second selective growth process may be executed using a third precursor including transition metal and a fourth precursor including a chalcogen element. The second semiconductor layer SL2 may include a transition metal dichalcogenide. The second seed pattern 132b and the second semiconductor layer SL2 may include the same transition metal element. According to some implementations, the fourth precursor includes selenium (Se), and the second semiconductor layer SL2 includes a transition metal diselenide.

The second preliminary auxiliary pattern 122b may include a material (e.g., crystalline aluminum oxide, amorphous aluminum oxide, or amorphous hafnium oxide) having a high bonding energy with the third and fourth precursors of the second selective growth process, or a material (e.g., crystalline aluminum oxide or boron nitride (BN)) having an identical or similar crystalline structure (e.g., an HCP or its similar crystalline structure) to that of the second semiconductor layer SL2. Thus, during the second selective growth process, the second preliminary auxiliary pattern 122b may assist a monocrystalline growth of the second semiconductor layer SL2.

After the formation of the second semiconductor layer SL2, the second mask pattern M2 may be removed. The second mask pattern M2 may be removed by, for example, an ashing process and/or a strip process.

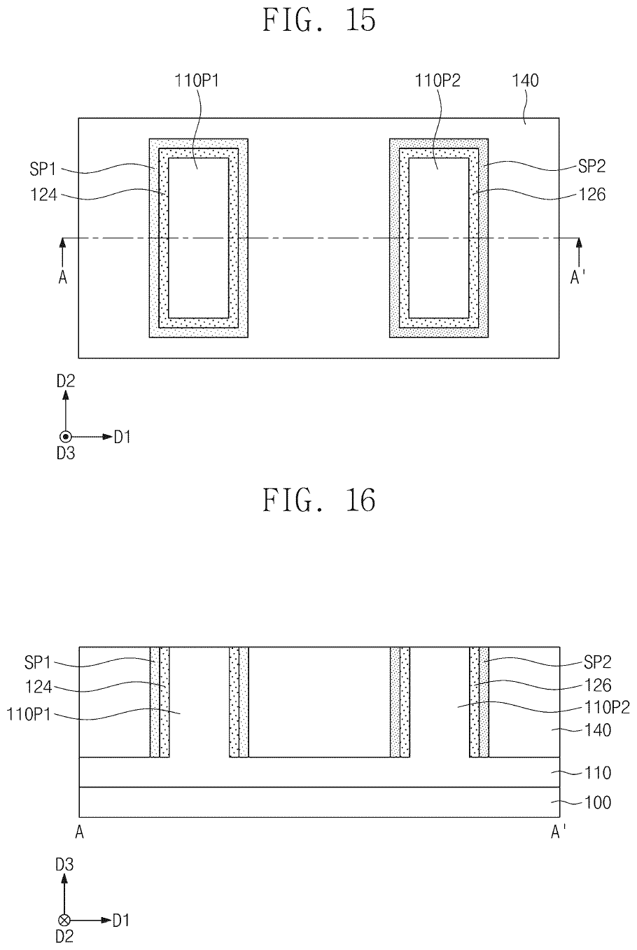

Referring to FIGS. 15 and 16, an upper dielectric layer 140 may be formed on the lower dielectric layer 110 to cover the first and second mold patterns 110P1 and 110P2, the first and second seed patterns 132a and 132b, the first and second preliminary auxiliary patterns 122a and 122b, and the first and second semiconductor layers SL1 and SL2. The upper dielectric layer 140 may include, for example, silicon oxide, silicon nitride, or silicon oxynitride.

A planarization process may remove an upper portion of the upper dielectric layer 140, the first and second seed patterns 132a and 132b, upper portions of the first and second preliminary auxiliary patterns 122a and 122b, and upper portions of the first and second semiconductor layers SL1 and SL2. The planarization process may be performed until the top surfaces of the first and second mold patterns 110P1 and 110P2 are exposed. As the planarization process removes the upper portions of the first and second preliminary auxiliary patterns 122a and 122b, a pair of first auxiliary patterns 124 may be correspondingly formed on the lateral surfaces of the first mold pattern 110P1, and a pair of second auxiliary patterns 126 may be correspondingly formed on the lateral surfaces of the second mold pattern 110P2. As the planarization process removes the upper portions of the first and second semiconductor layers SL1 and SL2, a pair of first semiconductor patterns SP1 may be correspondingly formed on the lateral surfaces of the first mold pattern 110P1, and a pair of second semiconductor patterns SP2 may be correspondingly formed on the lateral surfaces of the second mold pattern 110P2. The first auxiliary patterns 124 may be correspondingly interposed between the first semiconductor patterns SP1 and the first mold pattern 110P1, and the second auxiliary patterns 126 may be correspondingly interposed between the second semiconductor patterns SP2 and the second mold pattern 110P2.

The first semiconductor patterns SP1 may extend in the first direction D1 and the second direction D2 along the lateral surfaces of the first mold pattern 110P1 to connect with each other, thereby constituting a ring shape or other closed shape when viewed in plan. The first auxiliary patterns 124 may extend in the first direction D1 and the second direction D2 along the lateral surfaces of the first mold pattern 110P1 to connect with each other, thereby constituting a ring shape or other closed shape when viewed in plan. The ring-shaped first auxiliary patterns 124 may be interposed between the ring-shaped first semiconductor patterns SP1 and the first mold pattern 110P1.

The second semiconductor patterns SP2 may extend in the first direction D1 and the second direction D2 along the lateral surfaces of the second mold pattern 110P2 to connect with each other, thereby constituting a ring shape or other closed shape when viewed in plan. The second auxiliary patterns 126 may extend in the first direction D1 and the second direction D2 along the lateral surfaces of the second mold pattern 110P2 to connect with each other, thereby constituting a ring shape or other closed shape when viewed in plan. The ring-shaped second auxiliary patterns 126 may be interposed between the ring-shaped second semiconductor patterns SP2 and the second mold pattern 110P2.

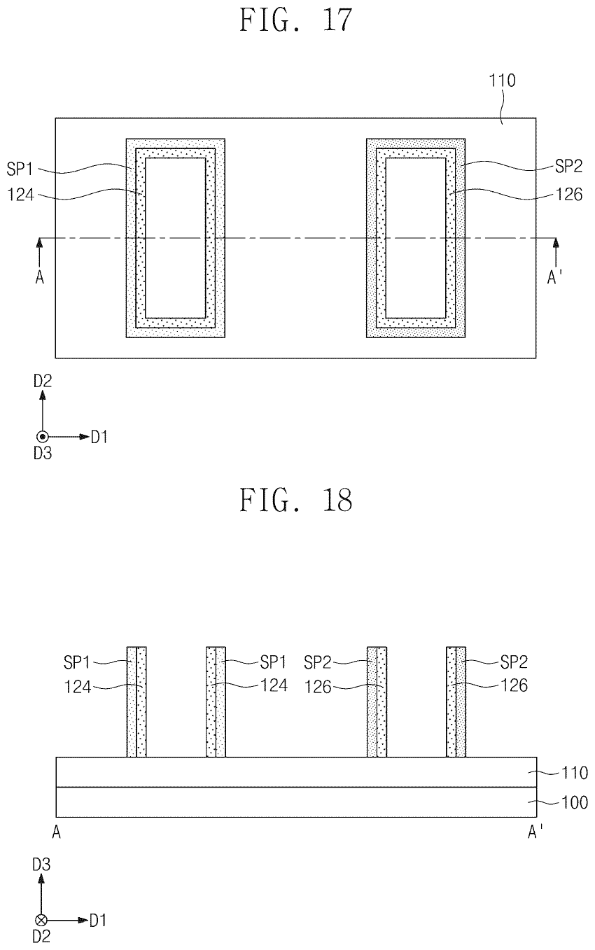

Referring to FIGS. 17 and 18, the upper dielectric layer 140 may be removed, and the first and second mold patterns 110P1 and 110P2 may also be removed. The removal of the upper dielectric layer 140 and the first and second mold patterns 110P1 and 110P2 may include, for example, allowing an etch-back process to recess the upper dielectric layer 140 and the first and second mold patterns 110P1 and 110P2. During the removal of the upper dielectric layer 140 and the first and second mold patterns 110P1 and 110P2, the first and second auxiliary patterns 124 and 126 may support the first and second semiconductor patterns SP1 and SP2.

Referring back to FIGS. 1 and 2A to 2C, a first gate dielectric layer GI1 may be formed to cover the first semiconductor patterns SP1 and the first auxiliary patterns 124, and a second gate dielectric layer GI2 may be formed to cover the second semiconductor patterns SP2 and the second auxiliary patterns 126. The formation of the first and second gate dielectric layers GI1 and GI2 may include, for example, forming on the lower dielectric layer 110 a gate dielectric layer that covers the first and second semiconductor patterns SP1 and SP2 and the first and second auxiliary patterns 124 and 126, and patterning the gate dielectric layer. As the gate dielectric layer is patterned, the second gate dielectric layer GI2 may be spaced apart horizontally (e.g., in the first direction D1) from the first gate dielectric layer GI1.

A first gate electrode GE1 may be formed on the first gate dielectric layer GI1, and may extend in the first direction D1 to extend across the first semiconductor patterns SP1 and the first auxiliary patterns 124. A second gate electrode GE2 may be formed on the second gate dielectric layer GI2, and may extend in the first direction D1 to extend across the second semiconductor patterns SP2 and the second auxiliary patterns 126. The formation of the first and second gate electrodes GE1 and GE2 may include, for example, forming on the lower dielectric layer 110 a gate electrode layer that covers the first and second gate dielectric layers GI1 and GI2, the first and second semiconductor patterns SP1 and SP2, and the first and second auxiliary patterns 124 and 126, and patterning the gate electrode layer. As the gate electrode layer is patterned, the second gate electrode GE2 may be spaced apart horizontally (e.g., in the first direction D1) from the first gate electrode GE1.

First source/drain electrodes SD1 may be formed on opposite sides of the first gate electrode GE1. On either side of the first gate electrode GE1, each of the first source/drain electrodes SD1 may cover the first semiconductor patterns SP1 and the first auxiliary patterns 124. Second source/drain electrodes SD2 may be formed on opposite sides of the second gate electrode GE2. On either side of the second gate electrode GE2, each of the second source/drain electrodes SD2 may be formed to cover the second semiconductor patterns SP2 and the second auxiliary patterns 126. The first and second source/drain electrodes SD1 and SD2 may be formed by using, for example, chemical vapor deposition or physical vapor deposition.

Accordingly, the seed pattern 132a/132b may be formed on a top surface of one mold pattern 110P1/110P2, and a selective growth process in which the seed pattern 132a/132b is used as a seed may be utilized to form a pair of semiconductor patterns SP1/SP2 on lateral surfaces of the mold pattern 110P1/110P2. Afterwards, the mold pattern 110P1/110P2 may be removed. For example, one mold pattern 110P1/110P2 may be used to easily form the pair of semiconductor patterns SP1/SP2, and thus it may be possible to easily increase an effective channel width of a fin field effect transistor including the semiconductor patterns SP1/SP2. In addition, a pair of auxiliary patterns 124/126 provided between the mold pattern 110P1/110P2 and the pair of semiconductor patterns SP1/SP2 may assist a monocrystalline growth of the semiconductor patterns SP1/SP2 and may support the semiconductor patterns SP1/SP2 during the removal of the mold pattern 110P1/110P2. The semiconductor patterns SP1/SP2 may be provided with easy crystalline growth in a stable fabrication process. Consequently, it may be possible to easily, more efficiently, or more reliably fabricate a fin field effect transistor having excellent channel characteristics.

According to some implementations of the present disclosure, a fin field effect transistor includes a pair of semiconductor patterns and a pair of auxiliary patterns between the pair of semiconductor patterns, and the semiconductor patterns include a transition metal dichalcogenide. As the fin field effect transistor includes the pair of semiconductor patterns, the fin field effect transistor may have an increased effective channel width (Weff). The auxiliary patterns may assist a monocrystalline growth of the semiconductor patterns, and may support the semiconductor patterns. Therefore, a crystalline growth of the semiconductor patterns may be easily and stably performed. As such, the fin field effect transistor may exhibit improved channel characteristics.

Accordingly, semiconductor device, such as a fin field effect transistors, with increased effective channel width and excellent channel characteristics may be provided.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The aforementioned description provides some examples for explaining concepts herein. Therefore, the present disclosure is not limited to the examples described above, and it will be understood by one of ordinary skill in the art that variations in form and detail may be made therein without departing from the spirit and essential features of the present disclosure.

What is claimed is:

1. A semiconductor device, comprising:
a semiconductor pattern on a substrate, the semiconductor pattern protruding in a direction perpendicular to a top surface of the substrate and having an inner surface and an outer surface that face opposite to each other in a first direction parallel to the top surface of the substrate;
a gate dielectric layer that covers the inner surface and the outer surface of the semiconductor pattern, the gate dielectric layer extending on a top surface of the semiconductor pattern;
a gate electrode on the gate dielectric layer, the gate electrode covering the outer surface, the top surface, and the inner surface of the semiconductor pattern; and
an auxiliary pattern between the gate dielectric layer and the inner surface of the semiconductor pattern,
wherein the outer surface of the semiconductor pattern is in contact with the gate dielectric layer, and
wherein the inner surface of the semiconductor pattern is in contact with the auxiliary pattern.

2. The semiconductor device of claim 1, wherein the gate dielectric layer contacts the top surface of the semiconductor pattern and extends on a top surface and a lateral surface of the auxiliary pattern.

3. The semiconductor device of claim 2, wherein the gate dielectric layer contacts the top surface and the lateral surface of the auxiliary pattern.

4. The semiconductor device of claim 1, wherein the semiconductor pattern includes a transition metal dichalcogenide.

5. The semiconductor device of claim 4, wherein the auxiliary pattern comprises at least one of a metal oxide or a metalloid nitride.

6. A semiconductor device, comprising:
a pair of semiconductor patterns on a substrate, the pair of semiconductor patterns at least partially spaced apart from each other in a first direction parallel to a top surface of the substrate and protruding in a direction perpendicular to the top surface of the substrate;
a pair of auxiliary patterns between the pair of semiconductor patterns and arranged on inner surfaces of the pair of semiconductor patterns, the inner surfaces facing each other in the first direction;
a gate dielectric layer that covers the pair of semiconductor patterns and the pair of auxiliary patterns and extends on the substrate between the pair of auxiliary patterns; and
a gate electrode on the gate dielectric layer, the gate electrode covering the pair of semiconductor patterns and the pair of auxiliary patterns and extending on the substrate between the pair of auxiliary patterns.

7. The semiconductor device of claim 6, wherein:
the pair of semiconductor patterns comprise outer surfaces that are opposite to the inner surfaces in the first direction, and
the outer surfaces of the pair of semiconductor patterns are in contact with the gate dielectric layer, and
the inner surfaces of the pair of semiconductor patterns are in contact with the pair of auxiliary patterns.

8. The semiconductor device of claim 7, wherein the gate dielectric layer contacts top surfaces of the pair of semiconductor patterns and extend on top surfaces and lateral surfaces of the pair of auxiliary patterns.

9. The semiconductor device of claim 6, wherein the pair of semiconductor patterns are continuous with one another.

10. The semiconductor device of claim 6, wherein:
the pair of semiconductor patterns and the pair of auxiliary patterns extend in a second direction that is parallel to the top surface of the substrate and crosses the first direction, and
the gate dielectric layer and the gate electrode extend in the first direction across the pair of semiconductor patterns and the pair of auxiliary patterns.

11. The semiconductor device of claim 10, wherein a length in the second direction of each of the pair of semiconductor patterns is greater than a width in the second direction of the gate dielectric layer.

12. The semiconductor device of claim 11, wherein a length in the second direction of each of the pair of auxiliary patterns is greater than the width in the second direction of the gate dielectric layer.

13. The semiconductor device of claim 11, wherein the width in the second direction of the gate dielectric layer is greater than a width in the second direction of the gate electrode.

14. The semiconductor device of claim 10, comprising first and second source/drain electrodes on respective opposite sides of the gate electrode in the second direction,
wherein the first and second source/drain electrodes cover the pair of semiconductor patterns and the pair of auxiliary patterns.

15. The semiconductor device of claim 6, wherein the pair of semiconductor patterns includes a transition metal dichalcogenide.

16. The semiconductor device of claim 15, wherein the pair of auxiliary patterns comprises at least one of a metal oxide or a metalloid nitride.

17. A semiconductor device, comprising:
a semiconductor pattern on a substrate and protruding in a direction perpendicular to a top surface of the substrate, wherein the semiconductor pattern has an inner surface and an outer surface face opposite to each other in a first direction parallel to the top surface of the substrate, and
wherein the semiconductor pattern extends in a second direction that is parallel to the top surface of the substrate and crosses the first direction;
an auxiliary pattern on the inner surface of the semiconductor pattern, the auxiliary pattern extending in the second direction;
a gate electrode that covers the semiconductor pattern and the auxiliary pattern and extends in the first direction across the semiconductor pattern and the auxiliary pattern;
a gate dielectric layer between the semiconductor pattern and the gate electrode, the gate dielectric layer extending between the auxiliary pattern and the gate electrode; and
first and second source/drain electrodes on respective opposite sides of the gate electrode in the second direction,
wherein the first and second source/drain electrodes cover the semiconductor pattern and the auxiliary pattern.

18. The semiconductor device of claim 17, wherein the semiconductor pattern includes a transition metal dichalcogenide.

19. The semiconductor device of claim 18, wherein the auxiliary pattern comprises at least one of a metal oxide or a metalloid nitride.

20. The semiconductor device of claim 17, wherein a width in the second direction of the gate dielectric layer is greater than a width in the second direction of the gate electrode.
